(19) United States
(12) Patent Application Publication
(10) Pub. No.: US 2005/0287446 A1
(43) Pub. Date: Dec. 29, 2005

(54) Method for the photolithographic projection of a pattern onto a semiconductor wafer with an alternating phase mask

(76) Inventor: Christoph Nolscher, Dresden (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/157,167

(22) Filed: Jun. 21, 2005

(30) Foreign Application Priority Data
Jun. 29, 2004 (DE) 10 2004031398.9

(51) Int. Cl. G03F 1/00; G03B 27/42; G03C 5/00

(52) U.S. Cl. 430/5; 430/311; 430/312; 430/313; 430/394; 355/53

(57) ABSTRACT

A method for the photolithographic projection of a pattern onto a semiconductor wafer with an alternating phase mask includes patterning a resist layer photolithographically with a pattern on the alternating phase mask via an exposure device in order to form a resist structure corresponding to the pattern. The pattern includes first linear structure elements having a first line width and a midpoint-to-midpoint distance, the first linear structure elements being chosen such that the elements of the resist structure which correspond with the first linear structures have a width corresponding approximately to the structure resolution of the exposure device, and have a midpoint-to-midpoint distance corresponding approximately to twice the structure resolution of the exposure device. A first distance from a structure element delimiting the linear structure elements is chosen such that the width of the region of the resist structure which corresponds with the absorber-free first partial region is less than four times the structure resolution of the exposure device.

### CROSS REFERENCE TO RELATED APPLICATIONS

This application claims priority under 35 U.S.C. §119 to German Application No. DE 10 2004031398.9, filed on Jun. 29, 2004, and titled “Method for the Photolithographic Projection of a Pattern onto a Semiconductor Wafer with an Alternating Phase Mask”, the entire contents of which are hereby incorporated by reference.

### FIELD OF THE INVENTION

The present invention relates to a method for photolithographic projection of a pattern onto a semiconductor wafer with an alternating phase mask.

### BACKGROUND

Integrated circuits are fabricated by a photolithographic projection of patterns formed on photomasks onto semiconductor wafers. Generally, a respective mask is used for each layer of the semiconductor wafer that is to be patterned, and such mask is provided with a pattern corresponding to the circuit.

Photomasks or reticles are used in the field of semiconductor fabrication in order to form a pattern of structure elements by lithographic projection onto a semiconductor wafer coated with a photosensitive resist. The choice of the lateral extent of the structure elements to be formed on the semiconductor wafer is restricted due to a lower resolution limit predetermined in particular by the projection system. The resolution limit depends, for example, on the exposure wavelength, the aperture size of the lens system, on the type of illumination source of the projection system, etc.

Large scale integrated circuits such as, by way of example, dynamic or nonvolatile memories and logic components, are currently fabricated with circuit elements with widths reaching to 70 nm. In memory components, this applies for example to the very densely and periodically arranged patterns of narrow word or bit lines and, if appropriate, the corresponding contact-connections or memory trenches.

Corresponding large scale integrated structure patterns of a circuit and the peripheral region that electrically connects the structure elements are often arranged together on the mask. Structure elements, such as interconnects, of the peripheral regions are usually subject to relaxed requirements made of the structure width. Accordingly, on the photomask that is to be used for forming the circuit, dense, often periodic arrangements of structure elements and also isolated or semi-isolated structure elements having larger dimensioning are arranged together in a pattern.

The resolution limit of a projection system can be reduced by using modern lithographic techniques in the case of the masks used for an exposure. This relates principally to the field of phase masks, which are also called phase shift masks.

A particularly high resolution is obtained if masks are used with improved lithography techniques (litho-enhancement techniques). This may be in particular phase masks of different types, such as, e.g., alternating phase masks, halftone phase masks, triton phase masks, chromeless phase masks, etc. However, the techniques mentioned may also involve those which improve the imaging properties during the projection of mask structures, for instance the use of OPC (Optical Proximity Correction) structures or sublithographic elements.

One example is alternating phase masks, which can be used to form particularly densely packed parallel lines in a layer on a semiconductor wafer. In this example, on the mask, transparent regions with a first and a second phase deviation are formed alternating in the interspaces between light-shading lines. The values for the respective phase deviation typically differ by 180°, but are not restricted to this exact value. Where the light-shading lines end on the mask, the problem arises that the two transparent regions having different phase deviations meet with one another, so that the phase jump brought about in this region leads to an undesirable shading of the resist on the semiconductor wafer during an exposure. In this respect, second masks, also called trimming masks, are used in order to eliminate the problem. The shadings in the resist that arise at phase jumps of the two transparent regions in a chromeless zone are postexposed by a second trimming mask. Using postexposure, these lines on the semiconductor wafer can be separated again by suitably positioned structure patterns on the trimming mask insofar as these are undesirable at specific conditions on the semiconductor wafer.

The trimming mask is used to postprocess, i.e. to “trim”, the structures exposed in the photosensitive resist on the semiconductor wafer by the first mask. The projection or exposure is effected partly into the regions in the photosensitive resist that have already exposed through the first mask, but also partly in regions in the resist that are shaded by the first mask.

The second masks of such a set that are used as trimming masks make it possible to use a particularly high-resolution mask type as a first mask without themselves being subject to these requirements. In particular, conventional masks which, under certain circumstances, are even exposed by an older type of mask writers can be used as trimming masks in a cost-saving manner. In the scenarios mentioned above, the task is to postexpose undesirable structures over a large area in a resist, where the requirements of the resolution are relatively low.

However, one known disadvantage arises by virtue of the fact that, in a desired trimming, for example, of long lines formed by alternating phase masks on a semiconductor wafer, the regions exposed through the first mask in the resist have an edge at which the radiation dose does not fall abruptly. This means that resist elements even outside the regions that are actually to be exposed have received a low radiation dose. During a postexposure, the trimming mask increases the received radiation dose thereof at a given position in the resist. The exposed regions therefore expand undesirably in the resist during an exposure with the trimming mask.

A further disadvantage results from the fact that the sequential exposure with two different sets of masks increases the processing time during semiconductor fabrication. On account of the mask change and the associated alignment and orientation sequences, the throughput is reduced in production.

One possible technique known in the art for working with an alternating phase mask without a trimming mask in a single exposure is the use of so-called “soft” phase jumps. This is understood to mean that a region with a phase jump of approximately 90° is inserted at those locations at which the two transparent regions having different phase deviations meet one another. What is thereby achieved is that only phase jumps of 90° occur, which do not lead to any undesirable shading of the resist on the semiconductor wafer during an exposure.

However, this procedure is practicable only under specific preconditions, since the available process window is greatly restricted on account of this measure. Particularly when both densely packed and semi-isolated structure elements of the pattern are intended to be imaged, the shading cannot be prevented with additional regions that effect phase-shifting through 90°.

### SUMMARY OF THE INVENTION

An object of the present invention is to provide a method that overcomes the abovementioned problems.

This and other objects are achieved according to the invention by a method for photolithographic projection of a pattern onto a semiconductor wafer with an alternating phase mask, the method including the following steps: providing the semiconductor wafer; applying a resist layer on a front side of the semiconductor wafer; providing an exposure device that includes a characteristic minimum structure resolution for an imaging of a structure element onto the resist layer; providing the alternating phase mask that comprises (a) the pattern including a first arrangement of first linear structure elements having a first line width and having a first midpoint-to-midpoint distance, and a first areal structure element arranged at a first distance from the first multiple arrangement; and (b) first regions and second regions made of transparent or semitransparent phase-shifting material, each of the first and second regions being arranged between the first linear structure elements and extending into an absorber-free first partial region arranged between the first arrangement and the first areal structure element, wherein, in forming the alternating arrangement, a first phase deviation surplus is assigned to each first region such that, within the first absorber-free region, phase boundaries arise directly between the first regions and second regions; and photolithographically patterning the resist layer with the pattern of the alternating phase mask by the exposure device so as to form a resist structure corresponding to the pattern, wherein the first line width is chosen such that the elements of the resist structure that correspond to the first linear structures have a width corresponding approximately to the structure resolution of the exposure device and have a midpoint-to-midpoint distance corresponding approximately to twice the structure resolution of the exposure device, and wherein the first distance is chosen such that the width of the region of the resist structure that corresponds to the absorber-free first partial region is less than four times the structure resolution of the exposure device.

Utilizing an alternating phase mask, the exposure of a densely packed structure is performed in only one exposure step. In order to prevent disturbing resist bridges in the region of the line ends of the linear structure elements, the distance from an areal structure element delimiting the linear structure elements is chosen such that no resist bridges are produced in the absorber-free region between the linear structure elements and the areal structure element when the different phase-shifting zones meet. The maximum distance between the linear structure elements and the areal structure element must not exceed four times the structure resolution of the exposure device if the linear structure elements are embodied as a densely packed structure having a minimum line width and midpoint-to-midpoint distance.

The above and still further objects, features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 schematically depicts an elevational view in cross-section of an exposure apparatus for application of a method according to the invention.

FIG. 2 schematically depicts a plan view of an embodiment of a pattern of structure elements.

FIG. 3 schematically depicts a partial view in plan of a pattern of structure elements.

FIG. 4 depicts a partial view in plan of a simulated resist structure after the exposure with the pattern of FIG. 3.

FIG. 5 schematically depicts a partial view in plan of a pattern of structure elements formed upon application of an exemplary method according to the invention.

FIG. 6 schematically depicts another partial view in plan of a pattern of structure elements formed upon application of a method according to the invention.

FIG. 7 schematically shows a further partial view in plan of a pattern of structure elements formed upon application of a method according to the invention.

FIG. 8 schematically depicts another partial view in plan of a pattern of structure elements formed upon application of a method according to the invention.

FIGS. 9A to 9C each schematically depict a partial view in plan of a simulated resist structure after exposure with the pattern of FIG. 7 or FIG. 8 upon application of a method according to the invention.

FIG. 10 is a flow diagram showing the steps of an embodiment of a method according to the invention.

### DETAILED DESCRIPTION

The invention is described below, by way of example, on the basis of embodiments for the projection of a pattern of structure elements onto a semiconductor wafer during the fabrication of an integrated circuit. However, the invention is not limited to such embodiments. Rather, the invention can also be used advantageously in the fabrication of other products in which a layer is to be patterned with a very high throughput in an exposure device. The pattern of structure elements is transferred onto a resist layer and subsequently into a layer of the semiconductor wafer. A person skilled in the art is aware that a multiplicity of layers are patterned during the fabrication of an integrated circuit and that further process steps, such as, for example, doping, planarization or chemical mechanical polishing, are also performed in order to achieve a functional integrated circuit.

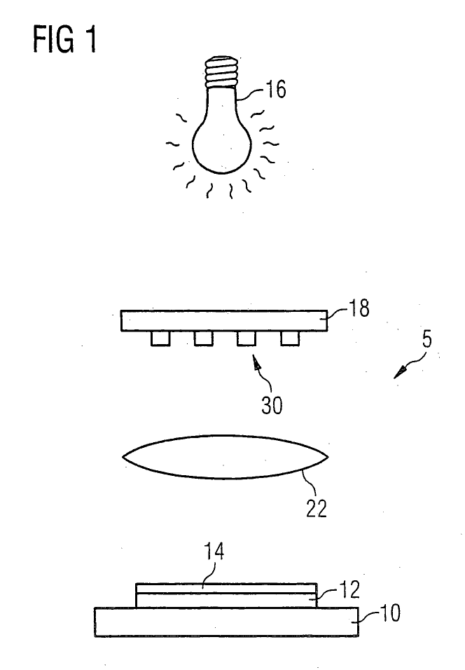

FIG. 1 shows, in a schematic elevational and cross-sectional view, the construction of a projection apparatus 5 that is the starting point of an embodiment of the method according to the invention. The projection apparatus 5 includes a movable substrate holder 10. A semiconductor wafer 12 is placed on the substrate holder 10. On the semiconductor wafer 12, a resist layer 14 is applied on a front side by, for example, spinning-on.

The projection apparatus 5 also includes a light source 16, which is arranged above the substrate holder 10 and is suitable for emitting light having a wavelength of 248 nm, 193 nm or 157 nm, for example. The light emitted by the light source 16 is projected through a projection objective 22 onto the front side of the semiconductor wafer 12.

A reticle 18 is fit between the light source 16 and the projection objective 22. The reticle 18 is provided with a pattern 30 of absorbing structure elements. In a wafer scanner, an exposure slot is fit between the reticle 18 and the projection objective 22 (not shown in FIG. 1). Through control of the substrate holder 10, the resist layer 14 on the front side of the semiconductor wafer 12 is progressively patterned in individual exposure fields.

The pattern of the structure elements is determined, for example, from a circuit design of a semiconductor memory having dynamic memory cells (DRAM) including trench capacitors which, in the region of the trench capacitors, has regularly arranged and densely packed linear structure elements with extremely small dimensions of 100 nm or less and, in the region of the peripheral logic provided for driving the memory cell array, has regularly arranged semi-isolated linear structure elements.

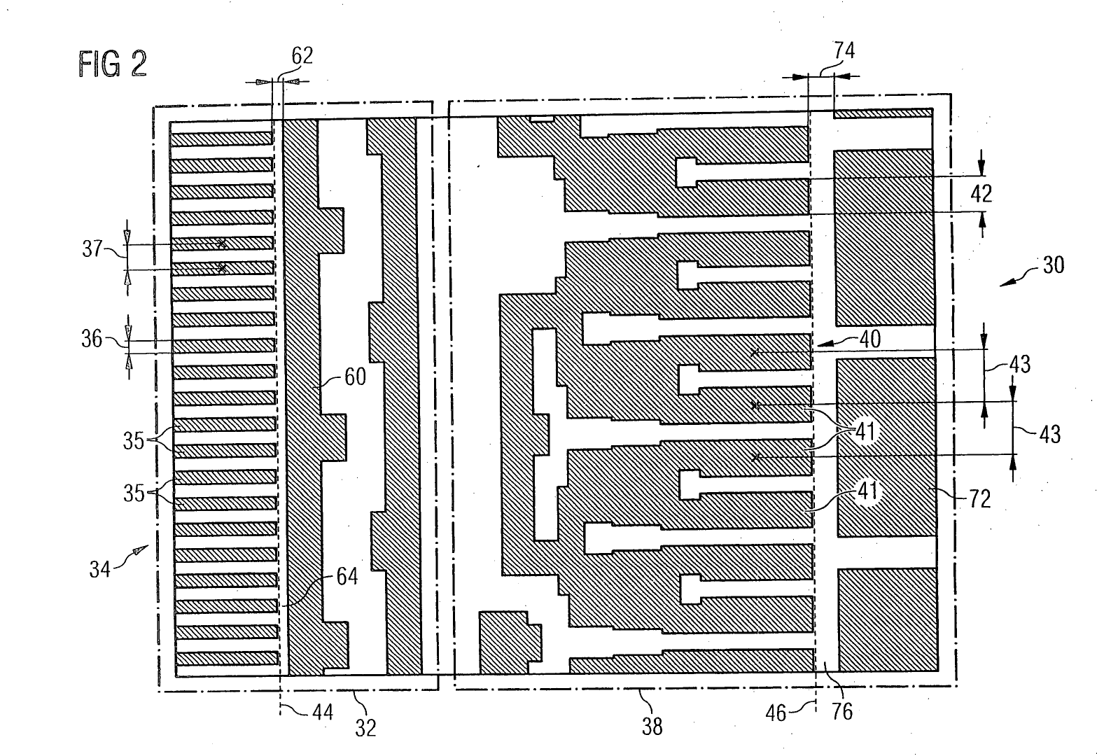

FIG. 2 shows an example of a pattern 30 of structure elements for fabricating a DRAM memory component. The pattern 30 has a first arrangement 34 of first linear structure elements 35 having a first line width 36 in a first part 32, which is depicted by a broken line in FIG. 1. The first linear structure elements 35 are arranged essentially parallel to one another. The first linear structure elements 35 in each case have an end point which, for each of the first linear structure elements 35, is arranged on a first auxiliary line 44. The end points are arranged in a manner spaced apart essentially equidistantly; in this case, their distance corresponds to the midpoint-to-midpoint distance 37 between the first linear structure elements 35 in the region of the end points. A first areal structure element 60 is arranged at a first distance 62 from the imaginary auxiliary line 44. Structure element 60 includes, on the side facing the first arrangement 34, a boundary line arranged essentially parallel to the auxiliary line 44. Consequently, a first partial region 64 having no absorbing structure elements is formed between the first arrangement 34 and the first areal structure element 60.

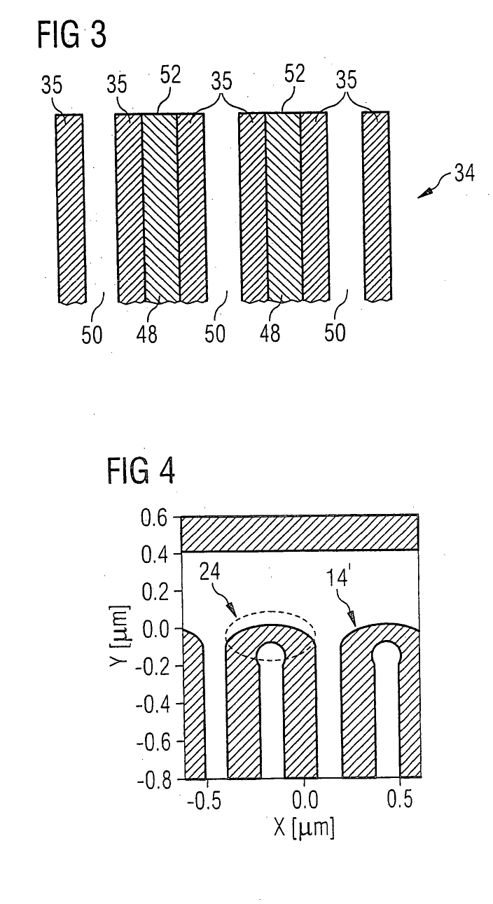

In order to form an alternating phase mask, a phase deviation is applied to every second interspace of the first linear structure elements 35. Phase boundaries occur in this case, as is shown in FIG. 3. The first regions 48 and the second regions 50 meet one another directly at the boundary lines 52 without being covered with an absorbing structure element.

In the case of a projection of the pattern 30 onto the resist layer 14, on account of the phase jump, as is known, undesirable lines may result in the resist, as shown in FIG. 4. FIG. 4 illustrates the simulation of a resist structure 14′ that would be produced in the case of an exposure with an alternating phase mask 18 having a pattern 30 in accordance with FIG. 3. Without further measures, resist bridges 24 occur in the region of the elements of the resist structure 14′ that correspond to the ends of the linear structure elements 35, and these resist bridges do not enable a functional circuit.

This forms the starting point for the method according to the invention. In a first embodiment, the first distance 62 is optimized. As described below, this can, for specific dimensions of the linear structure elements 35, prevent the occurrence of undesirable resist bridges 24 or suppress it to an extent such that possible residues of only partially formed resist bridges 24 can no longer have an influence on the function of the integrated circuit.

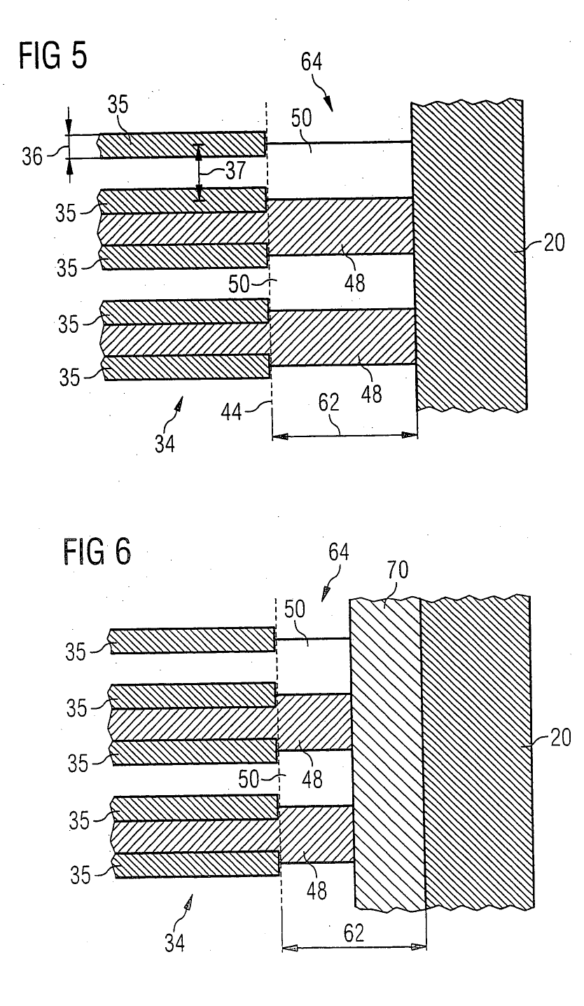

The pattern 30 of absorbing structure elements is illustrated in a partial view in FIG. 5. FIG. 5 shows the first arrangement 34 of the linear structure elements 35, the dimensions of which are chosen such that the lithographic patterning of the resist layer 14 gives rise to a resist structure whose elements corresponding to the dense linear structures 35 have a width corresponding approximately to the structure resolution of the exposure device 5, and have a midpoint-to-midpoint distance 37 corresponding approximately to twice the structure resolution of the exposure device 5. The first distance 62 is chosen such that the width of the region of the resist structure which corresponds to the absorber-free first partial region 64 is less than four times the structure resolution of the exposure device 5.

On account of the demagnifying projection of the exposure device 5, the dimensions of the structure elements of the alternating phase mask 18 are applied in a manner enlarged by a fixed factor, usually 4 to 5. Specifying the dimensions depending on the structure resolution of the exposure device 5 serves primarily for obtaining values that are independent of the exposure technology or the exposure wavelength. In this case, the structure resolution of the exposure device 5 follows the following calculation specification:
B_{MIN}=K₁*λ/NA,
where B_{MIN} represents the structure resolution of the exposure device 5, K₁ represents a factor dependent on the exposure technology, λ represents the exposure wavelength and NA represents the numerical aperture of the exposure device 5.

At the wavelength of 193 nm, together with the value of the numerical aperture that is between 0.6 and 1.0, a minimum structure resolution of approximately 50 nm to 70 nm results for the exposure device 5. Consequently, the width of the elements corresponding to the first linear structures 35 is approximately 65 nm given a midpoint-to-midpoint distance of 150 nm. The width of the region of the resist structure which corresponds to the absorber-free first partial region 64 is approximately 300 nm in this embodiment. With these dimensions, under the abovementioned properties of the exposure device 5, no disturbing resist bridges occur after the development of the resist layer. It has been shown in this case that the first distance 62, in particular, must not be chosen to be too large. By contrast, a value of the first distance 62 smaller than 300 nm does not have a disturbing effect.

In order to increase the associated process window, a further embodiment also provides for performing the exposure with a mask bias. Mask bias is understood generally to mean that the dimensions of the structure elements of the pattern of the mask are slightly enlarged, for example up to 10%. In order to achieve a dimensionally accurate imaging again during an exposure onto the resist layer 14, the exposure dose of the exposure device 5 is correspondingly increased. In the case of enlarging the dimensions of the structure elements of the pattern of the mask, the exposure dose is increased by up to a factor of 2, so that the exposure dose of the exposure device 5 is between 20 mJ/cm² and 50 mJ/cm².

As is shown in FIG. 2, the pattern 30 of structure elements has a second part 38, which is illustrated by a broken line. The second part of the pattern 30 includes a second arrangement 40 of second linear structure elements 41 having a second line width 42. The second linear structure elements 41 are arranged essentially parallel to one another with a midpoint-to-midpoint distance 43. The second linear structure elements 41 in each case have an end point which, for each of the second linear structure elements 41, is arranged on a second auxiliary line 46. A second areal structure element 72 is arranged at a second distance 74 from the imaginary auxiliary line 46, and the second structure element 72 includes, on the side facing the second arrangement 40, a boundary line arranged essentially parallel to the auxiliary line 46. Consequently, a second partial region 76 having no absorbing structure elements is likewise formed between the second arrangement 40 and the second areal structure element 72.

The dimensions of the second linear structure elements 41 are chosen such that the lithographic patterning of the resist layer 14 gives rise to a resist structure whose elements corresponding to the second linear structures 41 have a width corresponding approximately to twice the structure resolution of the exposure device 5, and have a midpoint-to-midpoint distance corresponding approximately to four times the structure resolution of the exposure device 5.

In this case, the second distance 74 is chosen such that the width of the region of the resist structure which corresponds to the absorber-free second partial region 76 is less than four times the structure resolution of the exposure device 5.

At the minimum structure resolution of the exposure device 5 of approximately 50 nm to 70 nm, the width of the elements corresponding to the second linear structures 41 is thus approximately 120 nm given a midpoint-to-midpoint distance of 200 nm. The width of the region of the resist structure which corresponds to the absorber-free second partial region 76 is approximately 600 nm in this embodiment. A value of the second distance 74 smaller than 600 nm does not have a disturbing effect. With these dimensions, under the abovementioned properties of the exposure device 5, no disturbing resist bridges occur after the development of the resist layer.

As a result, the corresponding choice of the first distance 62 and the second distance 74 affords a possibility of simultaneously imaging densely packed structures and semi-isolated structures with only a single exposure by means of an alternating phase mask without disturbing resist bridges. As an additional measure, as described above, a mask bias is also provided, which further reduces the occurrence of resist bridges.

This is advantageous particularly in the fabrication of random access memory components (DRAM). DRAM memory components often have, in the region of the memory cell array, trenches for trench capacitors and contact holes which have to be transferred as densely packed structure elements onto the resist layer 14 of the semiconductor wafer 10. Furthermore, DRAM memory components have a peripheral logic for driving the memory cell array, which comprises a pattern of isolated or semi-isolated lines. The first linear structures 35 are suitable for forming the pattern in the region of the trench capacitors and/or contact holes. The second arrangement 40 of second linear structure elements 41 is for example a part of the pattern of the peripheral logic of the memory cell array.

It is furthermore provided that the first linear structure elements 35 are provided with structures for optical proximity correction in the region of the ends of the first linear structure elements. In addition to the elements for an optical proximity correction (OPC) that are known in the art, provision is also made for using sublithographic structure elements in the vicinity of structure elements to be imaged. The second linear structure elements 41 in the region of the ends of the second linear structure elements may likewise be provided with structures for optical proximity correction.

The pattern 30 of absorbing elements is usually applied in the form of a patterned metal layer on a transparent or semitransparent phase-shifting material. The metal layer is usually produced from chromium; e.g. molybdenum silicide (MoSi) is used for the phase-shifting material.

Further embodiments are described below which, either individually or accumulatively, make it possible to increase the process window and to further reduce the occurrence of resist bridges.

In one further embodiment, the semiconductor wafer 12 is oriented on the substrate holder 10 such that the resist layer 14 does not lie in an optimum focal plane. This is achieved for example by displacing the position of the resist layer 14 in the direction of the projection objective 22 or in the opposite direction, so that the position of the resist layer 14 deviates by approximately 0.1 μm to 0.5 μm from the focal plane of the exposure device 5.

The deviation from the optimum focal plane may be achieved, for example in the case of a wafer scanner as exposure device 5, by tilting the substrate holder 10 during the photolithographic patterning. This deviation leads to a suppression of the resist bridges.

In one further embodiment, a third region 70 made of transparent or semitransparent phase-shifting material is arranged in the absorber-free first partial region 64. The third region is situated on that side of the absorber-free first partial region 64 which is remote from the first arrangement 34, as is shown in FIG. 6 in a partial view of the first part of the pattern 30.

Afterward, the second region 50 is assigned a second phase deviation surplus and the third region 70 is assigned a third phase deviation surplus, the second phase deviation surplus being chosen so as to produce an alternating arrangement together with the first phase deviation surplus of the first region 48. In a first example, the first phase deviation surplus is approximately 0 degrees, the second phase deviation surplus is approximately 180 degrees and the third phase deviation surplus is approximately 90 degrees. In a further example, the first phase deviation surplus is approximately 90 degrees, the second phase deviation surplus is approximately 270 degrees and the third phase deviation surplus is approximately 0 degrees. The first and second phase deviation surpluses have a phase difference of 180 degrees in both examples. The third phase deviation surplus has a phase difference of 90 degrees with respect to the first and second phase deviation surpluses in both examples. The third region 70 acts like a soft phase transition in the absorber-free first partial region toward the absorbing areal structure element 20, which reduces the occurrence of undesirable resist bridges (24).

In one further embodiment, the concept just described is also applied to the second absorber-free partial region 76. For this purpose, a fourth region 78 made of transparent or semitransparent phase-shifting material is arranged on the side remote from the second arrangement 40 in the second absorber-free region 76, which is subsequently assigned a fourth phase deviation surplus. As in the case above, the first phase deviation surplus may be approximately 0 degrees, the second phase deviation surplus approximately 180 degrees and the fourth phase deviation surplus approximately 90 degrees. A different assignment, in which e.g. the first phase deviation surplus is approximately 90 degrees, the second phase deviation surplus is approximately 270 degrees and the fourth phase deviation surplus is approximately 0 degrees, is likewise provided. In practice, the third region 70 and the fourth region 78 will have the same phase deviation surplus in order not to unnecessarily complicate the fabrication of the alternating phase mask 18.

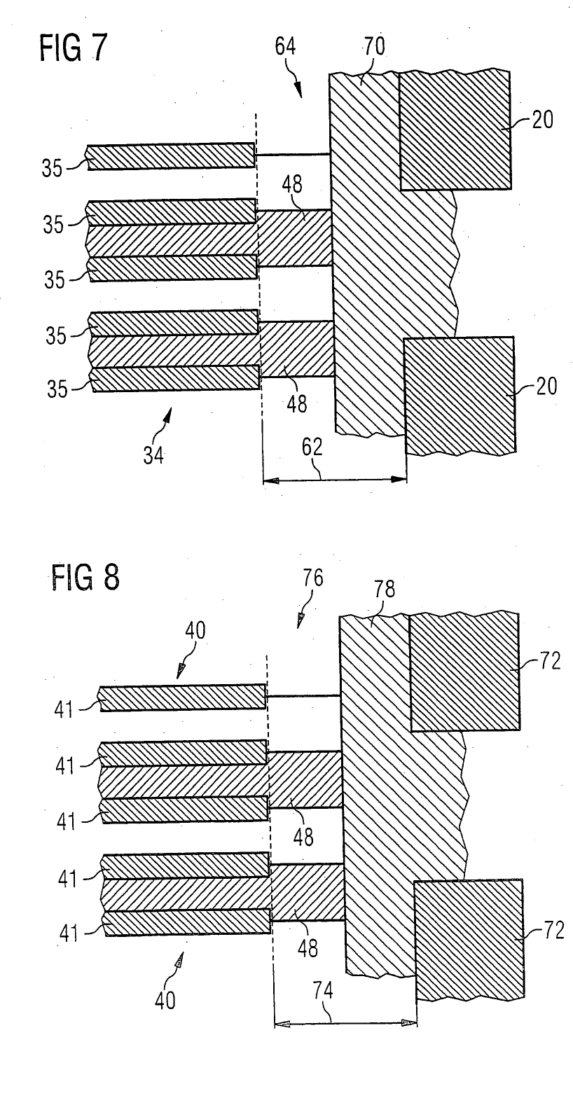

FIG. 7 shows the first areal structure element 20 in a further embodiment, said structure element having one or more cutouts on the side facing the first arrangement 34. This occurs, for example, when the first areal structure element 20 has a gap on account of the circuit design. The first areal structure element 20 is limited by a boundary line oriented essentially perpendicular to the first linear structure elements 34. It is found in the context of simulation calculations that the imaging of this pattern 30 does not bring about any resist bridges if the measures described above are applied.

FIG. 8 shows the second areal structure element 72, which likewise has one or more further cutouts on the side facing the second arrangement 40 and is oriented along a boundary line arranged essentially perpendicular to the second linear structure elements 40. The imaging of this pattern 30 likewise does not bring about any resist bridges, particularly if the soft phase transition by means of the fourth region 78 is employed.

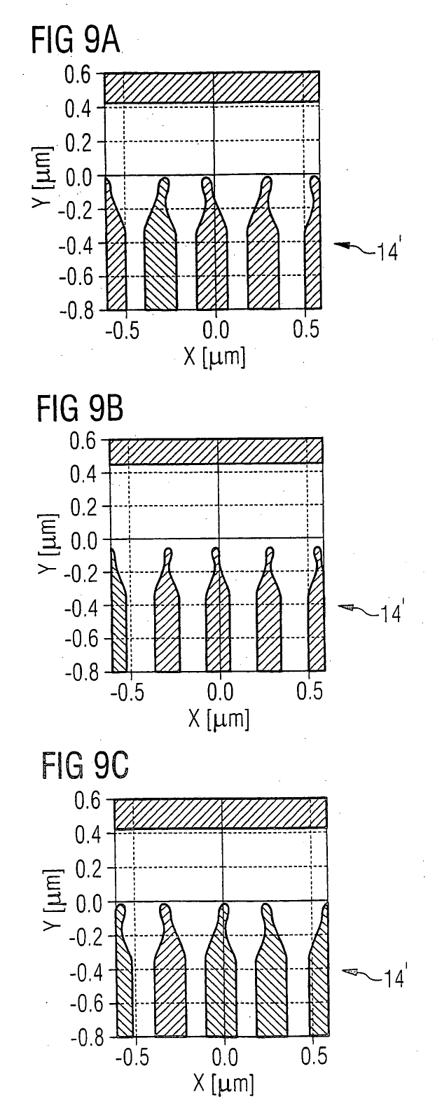

FIGS. 9A to 9C show results of simulation calculations. The resist structure 14′ which is produced after patterning with the second arrangement 40 was calculated for three different focus conditions. In this case, during the exposure a defocus of −0.3 μm was assumed in FIG. 9A, a defocus of −0.1 μm was assumed for FIG. 9B and a defocus of +0.1 μm was assumed for FIG. 9C. In this case, the value specified relates to the displacement of the resist structure during the exposure from the focal plane of the exposure device 5. It is evident that no resist bridges arise for all three exposure conditions.

The invention has provided a possibility for imaging a pattern of densely packed structure elements together with a pattern of isolated or semi-isolated structure elements onto a resist layer in a single exposure step with an alternating phase mask. In particular, the use of a trimming mask for eliminating resist bridges may be obviated.

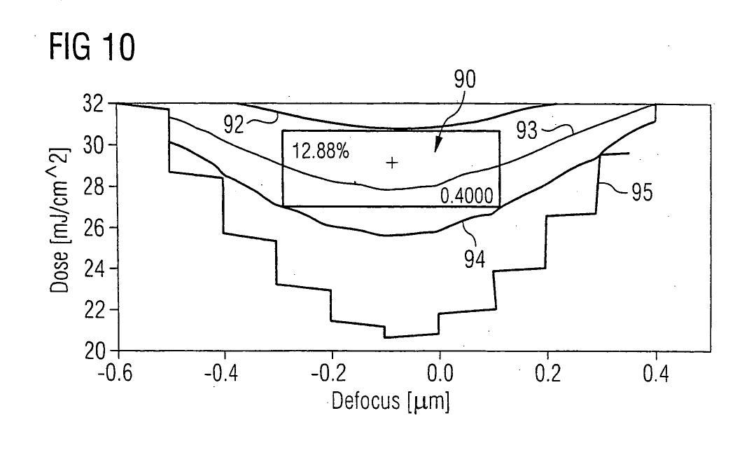

FIG. 10 shows in a diagram, by way of example, the available process window that results in the case of the production method according to FIGS. 9A to 9C. In FIG. 10, the exposure dose is plotted as a function of the defocusing of the exposure. In this case, specific limit values of parameters which are suitable for the characterization of the resist structure formed during the exposure are depicted in order to delimit the available process window.

In FIG. 10, the process window 90 is delimited by the maximum and minimum tolerable deviation of the line width on the resist structure, which are represented as first curve 92 and as second curve 94. The dimensionally accurate imaging is depicted in a third curve 93 for illustration. A fourth curve 95 restricts the process window to the effect that the elements of the resist structure must have an inclination of the sidewalls which is to lie in an angular range of 85 degrees to 92 degrees.

As a result, an available process window 90 is provided which permits a defocusing in a range of 0.4 μm given a variation of the exposure dose of approximately 15%. This is approximately comparable with exposures of other production processes and is suitable for the production of integrated circuits in a modern high-volume process line.

While the invention has been described in detail and with reference to specific embodiments thereof, it will be apparent to one skilled in the art that various changes and modifications can be made therein without departing from the spirit and scope thereof. Accordingly, it is intended that the present invention covers all modifications and variations of this invention that come within the scope of the appended claims and their equivalents.

List of Reference Symbols

5 Exposure device
10 Substrate holder
12 Semiconductor wafer
14 Resist layer
14′ Resist structure
16 Light source
18 Alternating phase mask
20 First areal structure element
22 Projection objective
24 Resist bridge
30 Pattern
32 First part of the pattern
34 First arrangement
35 First linear structure element
36 First line width
37 First midpoint-to-midpoint distance
38 Second part of the pattern
40 Second arrangement
41 Second linear structure element
42 Second line width
43 Second midpoint-to-midpoint distance
44 First auxiliary line
46 Second auxiliary line
48 First region
50 Second region
52 Boundary line
54 First width
56 Second width
60 First frame
62 First distance
64 First partial region
70 Third region
72 Second frame
74 Second distance
76 Second areal structure element
78 Fourth region
90 Process window
92 First curve
93 Second curve
94 Third curve
95 Fourth curve

1. A method for the photolithographic projection of a pattern onto a semiconductor wafer with an alternating phase mask, comprising:
providing the semiconductor wafer;
applying a resist layer on a front side of the semiconductor wafer;
providing an exposure device that includes a characteristic minimum structure resolution for imaging a structure element onto the resist layer;
providing the alternating phase mask that comprises:
the pattern comprising a first arrangement of first linear structure elements, each first linear structure element having a first line width with a first midpoint-to-midpoint distance being defined between midpoints of adjacent first linear structure elements, and a first areal structure element arranged at a first distance from the first arrangement; and
first regions and second regions made of transparent or semitransparent phase-shifting material, each of the first and second regions being arranged between the first linear structure elements and extending into an absorber-free first partial region that is arranged between the first arrangement and the first areal structure element, wherein, in order to form an alternating arrangement, a first phase deviation surplus is assigned to each first region such that, within the absorber-free first partial region, phase boundaries arise directly between the first regions and the second regions; and
photolithographically patterning the resist layer with the pattern of the alternating phase mask by the exposure device in order to form a resist structure corresponding with the pattern, wherein the first line width is chosen such that the elements of the resist structure that correspond with the first linear structures have a width corresponding approximately with the structure resolution of the exposure device and have a midpoint-to-midpoint distance between midpoints of adjacent resist structures corresponding approximately with twice the structure resolution of the exposure device, and the first distance is chosen such that a width of a region of the resist structure that corresponds with the absorber-free first partial region is less than four times the structure resolution of the exposure device.

2. The method of claim 1, wherein the exposure device includes a light source and a projection objective, and the minimum structure resolution of the exposure device results from a numerical aperture and a wavelength of emitted light of the light source.

3. The method of claim 2, wherein the exposure device includes a minimum structure resolution of approximately 50 nm to 70 nm at a wavelength of 193 nm, and the value of the numerical aperture is between 0.6 and 1.0.

4. The method of claim 3, wherein the width of the elements corresponding with the first linear structures is approximately 65 nm, the midpoint-to-midpoint distance is 150 nm, and the width of the region of the resist structure that corresponds with the absorber-free first partial region is less than 300 nm.

5. The method of claim 1, further comprising, prior to the providing of the phase mask:
defining the first line width of the first linear structures elements;
defining an exposure dose of the exposure device such that the first linear structure elements are imaged dimensionally accurately onto the resist layer in an exposure;
enlarging the first line width of the first linear structure elements by up to 10%; and
increasing the exposure dose of the exposure device, such that the photolithographically patterning of the resist layer is subsequently performed with a mask bias so as to accurately dimensionally image the first linear structure elements.

6. The method of claim 5, wherein the width of the elements corresponding with the first linear structures is approximately 65 nm, the midpoint-to-midpoint distance is 150 nm, and the exposure dose of the exposure device is between 20 mJ/cm² and 50 mJ/cm².

7. The method of claim 1, wherein the first arrangement of first linear structure elements is configured to form a part of a pattern of a memory cell array with trenches for trench capacitors and contact holes in the region of the trench capacitors and/or contact holes.

8. The method of claim 1, wherein the pattern comprises a second arrangement of second linear structure elements, each of the second linear structure elements having a second line width with a second midpoint-to-midpoint distance defined between midpoints of adjacent second linear structure elements, and a second areal structure element arranged at a second distance from the second arrangement, first regions and second regions made of transparent or semitransparent phase-shifting material and each of the first and second regions being arranged between the first linear structure elements and extending into a second absorber-free region arranged between the second arrangement and the second areal structure element.

9. The method of claim 8, wherein the second line width is selected such that the elements of the resist structure that correspond with the first linear structures have a width corresponding approximately with twice the structure resolution of the exposure device, and the midpoint-to-midpoint distance between midpoints of adjacent elements of the resist structure are approximately four times the structure resolution of the exposure device, and the second distance is selected such that the width of the region of the resist structure which corresponds with the second absorber-free region is less than ten times the structure resolution of the exposure device.

10. The method of claim 9, wherein the width of the elements corresponding with the second linear structure elements is approximately 200 nm, the midpoint-to-midpoint distance between midpoints of adjacent elements is 300 nm, and the width of the region of the resist structure which corresponds with the second absorber-free region is less than 600 nm.

11. The method of claim 8, wherein the second arrangement of second linear structure elements is configured to form a part of a pattern of a peripheral logic of a memory cell array.

12. The method of claim 1, wherein, in the photolithographically patterning of the resist layer with the alternating phase mask, the resist layer deviates in magnitude by 0.1 μm to 0.5 μm from an optimum focal plane of the exposure device.

13. The method of claim 12, wherein the exposure device is a wafer scanner including a substrate holder configured to receive the semiconductor wafer, and the substrate holder is tilted during the photolithographic patterning in order to achieve the deviation from the optimum focal plane.

14. The method of claim 1, wherein the providing the alternating phase mask further comprises:
arranging a third region made of transparent or semitransparent phase-shifting material on a side remote from the first arrangement in the absorber-free first partial region;
assigning a third phase deviation surplus to the third region; and
assigning a second phase deviation surplus to the second region for forming the alternating arrangement.

15. The method of claim 14, wherein the first phase deviation surplus is approximately 0 degrees, the second phase deviation surplus is approximately 180 degrees and the third phase deviation surplus is approximately 90 degrees.

16. The method of claim 14, wherein the first phase deviation surplus is approximately 90 degrees, the second phase deviation surplus is approximately 270 degrees and the third phase deviation surplus is approximately 0 degrees.

17. The method of claim 14, wherein the providing of the alternating phase mask further comprises:
arranging a fourth region made of transparent or semitransparent phase-shifting material on a side remote from the first arrangement in the absorber-free first partial region; and
assigning a fourth phase deviation surplus to the fourth region.

18. The method of claim 17, wherein the first phase deviation surplus is approximately 0 degrees, the second phase deviation surplus is approximately 180 degrees and the fourth phase deviation surplus is approximately 90 degrees.

19. The method of claim 17, wherein the first phase deviation surplus is approximately 90 degrees, the second phase deviation surplus is approximately 270 degrees and the fourth phase deviation surplus is approximately 0 degrees.

20. The method of claim 17, in which the third region and the fourth region have the same phase deviation surplus.

21. The method of claim 1, wherein the first areal structure element includes, on a side facing the first arrangement, a boundary line oriented substantially perpendicular to the first linear structure elements and one or more cutouts.

22. The method of claim 8, wherein the second areal structure element includes, on a side facing the second arrangement, a boundary line oriented substantially perpendicular to the second linear structure elements and one or more further cutouts.

23. The method of claim 1, wherein the first linear structure elements are provided with structures for optical proximity correction in the region of the ends of the first linear structure elements.

24. The method of claim 8, wherein the second linear structure elements are provided with structures for optical proximity correction in the region of the ends of the second linear structure elements.

25. The method of claim 1, wherein the pattern is applied in the form of a patterned metal layer on the transparent or semitransparent phase-shifting material.
